(19) United States
(12) Patent Application Publication
(10) Pub. No.: US 2025/0275064 A1
(43) Pub. Date: Aug. 28, 2025

(54) ELECTRONIC DEVICE, PRINTED CIRCUIT BOARD MODULE THEREFOR, AND PRINTED CIRCUIT BOARD RETAINING APPARATUS FOR USE THEREWITH

(71) Applicant: UBICQUIA, INC., FORT LAUDERDALE, FL (US)

(72) Inventors: Claudio Santiago Ribeiro, Evanston, IL (US); Cesar Eduardo Nunez, Miramar, FL (US)

(21) Appl. No.: 19/063,000

(22) Filed: Feb. 25, 2025

Related U.S. Application Data
(60) Provisional application No. 63/557,724, filed on Feb. 26, 2024.

(51) Int. Cl. H05K 5/00; G01J 1/04

(52) U.S. Cl. CPC H05K 5/0026; G01J 1/0403

(57) ABSTRACT

A retaining apparatus for a printed circuit board (PCB) includes a support member, flexible finger members positioned proximate a periphery of the support member, and at least one wall member. The support member has a first side and a second side (e.g., a top side and an underside). Each finger member extends away from the second side of the support member and has a restoring force toward the center of the support member. Each wall member also extends away from the second side of the support member and is sized and shaped to restrict deflection of at least one area of the PCB in the event that the PCB is subjected to at least one externally applied force after being positioned between the finger members. The retaining apparatus and the PCB may together form a PCB module for use in an electronic device, such as an Internet of Things sensor.

### CROSS-REFERENCE TO RELATED APPLICATIONS

The present application claims the benefit of and priority upon U.S. Provisional Patent Application No. 63/557,724, which was filed on Feb. 26, 2024, and is incorporated herein by this reference as if fully set forth herein.

### TECHNICAL FIELD

The present disclosure relates generally to a retaining apparatus for a printed circuit board (PCB) and, more particularly, to a multi-fingered PCB retaining apparatus with deflection-mitigating wall members.

### BACKGROUND

Printed circuit boards (PCBs) are typically installed in electronic devices by clipping or fastening (e.g., with screws) the PCBs to base substrates, stand-offs, or electronic device housings. However, such mounting techniques can prove to be inadequate to mitigate stresses on and damage to the PCBs and their components used in smaller-sized electronic devices that may be subject to extreme stresses, such as from being dropped or falling from heights of 20 feet or more.

### SUMMARY

According to exemplary embodiments of the present disclosure, a retaining apparatus for a printed circuit board (PCB) includes a support member, multiple (i.e., two or more) flexible finger members positioned proximate a periphery of the support member, and at least one wall member. The support member has a first side and a second side (e.g., a top side and a bottom or underside). Each of the finger members extends away from the second side of the support member and has a restoring force (e.g., a spring force) toward the center of the support member. The at least one wall member also extends away from the second side of the support member and is sized and shaped to restrict deflection of at least one area of the PCB in the event that the PCB is subjected to an externally applied force (e.g., due to mechanical shock or otherwise) after the PCB is inserted between the finger members. The restoring forces of the finger members help grip and retain the PCB after positioning of the finger members about the PCB.

According to alternative exemplary embodiments of the retaining apparatus, the support member includes a substantially flat section (e.g., in a central portion on a top side of the support member) and an angled section joined to the substantially flat section. In such embodiments, the angled section extends from the flat section to the periphery of the support member such that an outer edge of the angled section defines the periphery of the support member. In one exemplary embodiment, the flat section of the support member has a generally circular shape, although such flat section may have a different shape where necessitated by a design of the retaining apparatus.

According to other alternative exemplary embodiments of the present disclosure, the retaining apparatus further includes a light guide or light pipe positioned between the support member and an expected location of a light sensor secured to the PCB. For example, the light guide may be generally cylindrically or conically shaped and either pass through an aperture in the flat section of the support member or extend from the top surface of the support member toward where the PCB will be positioned between the finger members such that an input to the light guide is on or even (e.g., level) with the top side or surface of the support member and an output of the light guide resides a few millimeters above the maximum height of the light sensor secured to the PCB.

According to one or more further alternative embodiments of the retaining apparatus, some or all of the finger members include tabs on their inward-facing sides (i.e., the sides facing the center of the support member). For finger members that include such tabs, the tabs may be located near the distal ends of the finger members (i.e., the ends that are not attached to the support member). The tabs provide support for the PCB upon positioning the finger members about the PCB. For example, the PCB may be positioned between the finger members of the retaining apparatus by pushing the PCB between the finger members so that the PCB rests upon the finger member tabs. Alternatively, the PCB may be positioned between the finger members of the retaining apparatus by pushing the retaining apparatus down over the PCB such that the finger members separate to accept the PCB and then apply their restoring forces to corresponding outer peripheral areas of the PCB to retain it. The restoring forces exerted by the finger members grip the edge of the PCB to retain it in place upon the tabs. According to one exemplary embodiment, at least three of the finger members include tabs on their inward-facing sides.

According to other alternative exemplary embodiments of the present disclosure, the retaining apparatus includes multiple (two or more) wall members. The wall members may be arranged and configured to reside just above (e.g., 2-25 millimeters (mm) above) components on the PCB and/or sections of the PCB. Thus, in some embodiments of the retaining apparatus, the wall members are positioned and configured to restrict deflections of areas of the PCB where components are secured or attached (e.g., soldered, glued, press-fit, etc.) or in other sensitive areas. According to other alternative embodiments of the retaining apparatus, at least the support member, the finger members, and the wall member(s) are formed as a single molded (e.g., injection molded) component. Alternatively, the entire retaining apparatus may be formed as a single molded component.

According to other exemplary embodiments of the present disclosure, a PCB module includes a retaining apparatus and a PCB. The retaining apparatus includes a support member, multiple flexible finger members positioned proximate a periphery of the support member, and at least one wall member. The PCB has at least one component attached thereto. The support member of the retaining apparatus has a first side and a second side (e.g., a top side and an underside). Each finger member of the retaining apparatus extends away from the second side of the support member and has a restoring force (e.g., a spring force) toward the center of the support member. Each wall member of the retaining apparatus also extends away from the second side of the support member. The PCB is retained by and between the finger members of the retaining apparatus (e.g., by the restoring forces of the finger members). Each wall member of the retaining apparatus is sized and shaped to restrict deflection of at least one area of the PCB in the event that the PCB is subjected to an externally applied force (e.g., due to mechanical shock or otherwise).

According to one or more alternative exemplary embodiments of the present disclosure, the PCB module includes at least one antenna disposed at least partially on the first side (e.g., the top side) of the support member of the retaining apparatus. Where the electronic device functions as a networked device, such as a networked sensor or Internet of Things (IoT) device, for example, the at least one antenna may be or include an antenna operating at cellular (e.g., LTE or 5G) frequency bands or a Wi-Fi antenna. The at least one antenna may also include an antenna operable to receive global navigation satellite system (GNSS) signals, such as global positioning system (GPS) signals.

According to one or more other alternative embodiments of the PCB module, the support member of the retaining apparatus includes a substantially flat section (e.g., in a central portion on the top side of the support member) and an angled section joined to the substantially flat section. In these embodiments, the angled section extends from the flat section to the periphery of the support member such that an outer edge of the angled section defines the periphery of the support member. In other alternative embodiments of the retaining apparatus, the flat section of the support member has a generally circular shape, although other shapes may be used.

According to one or more further exemplary alternative embodiments of the PCB module, at least one of the components attached to the PCB is a light sensor and the PCB module further includes a light guide or light pipe. In these embodiments, the light guide is positioned to direct incident light toward the light sensor. For example, the light guide may be generally cylindrically or conically shaped and either pass through an aperture in the flat section of the retaining apparatus' support member or otherwise extend from the top surface of the retaining apparatus' support member toward the PCB such that an input to the light guide is on or even (e.g., level) with the top side or surface of the support member and an output of the light guide resides a few millimeters (e.g., 2-25 mm) above the light sensor on the PCB.

According to one or more other alternative embodiments of the PCB module, at least some of the finger members of the retaining apparatus include tabs on their inward-facing sides. In these embodiments, peripheral areas of the PCB rest upon the tabs such that the tabs provide support for the PCB. According to one exemplary embodiment, at least three retaining apparatus finger members include tabs on their inward-facing sides.

According to one or more further exemplary alternative embodiments of the PCB module, the retaining apparatus includes multiple wall members. The wall members may be arranged and configured to reside just above (e.g., 2-25 mm above) components on the PCB and/or sections of the PCB. Thus, the wall members are positioned and configured to restrict deflections of areas of the PCB where components are secured or attached (e.g., soldered, glued, press-fit, etc.) or in other sensitive areas. According to one or more other alternative embodiments of the PCB module, at least the support member, the finger members, and the wall member(s) of the retaining apparatus are formed as a single molded (e.g., injection molded) component. Alternatively, the entire retaining apparatus is formed as a single molded component.

According to one or more additional alternative embodiments of the present disclosure, a PCB module includes a multi-wall retaining apparatus and a PCB. In these embodiments, the retaining apparatus includes a support member, multiple flexible finger members positioned proximate a periphery of the support member, and two or more wall members. The PCB has multiple components attached thereto. The support member of the retaining apparatus has a first side and a second side (e.g., a top side and an underside). Each finger member of the retaining apparatus extends away from the second side of the support member and has a restoring force (e.g., a spring force) toward the center of the support member. Each wall member of the retaining apparatus also extends away from the second side of the support member. The PCB is retained by and between the finger members of the retaining apparatus (e.g., by restoring forces of the finger members). The wall members of the retaining apparatus are sized and shaped to restrict deflections of multiple areas of the PCB in the event that the PCB is subjected to at least one externally applied force.

According to some exemplary embodiments of the alternative PCB module, the PCB module includes a light guide or light pipe positioned to direct incident light toward a light sensor, where the light sensor is one of the components on the PCB. For example, the light guide may be generally cylindrically or conically shaped and either pass through an aperture in the flat section of the retaining apparatus' support member or extend from the top surface of the retaining apparatus' support member toward the PCB such that an input to the light guide is on or even (e.g., level) with the top side or surface of the support member and an output of the light guide resides a few millimeters (e.g., 2-25 mm) above the light sensor on the PCB.

According to other embodiments of the alternative PCB module, the PCB module further includes at least one antenna disposed at least partially on the first side of the support member of the retaining apparatus. Where the electronic device functions as a networked device, such as a networked sensor or IoT device, for example, the antenna may be or include an antenna operating at cellular (e.g., LTE or 5G) frequency bands or a Wi-Fi antenna. The PCB module may also include an antenna operable to receive GNSS signals, such as GPS signals. Other exemplary embodiments of the alternative PCB module may include various elements and modifications as described in more detail above and below.

According to one or more alternative exemplary embodiments of the present disclosure, an electronic device, such as a networked lighting controller, sensor, or other IoT device, includes a PCB module and a base member. The PCB module includes a retaining apparatus and a PCB. The PCB is positioned upon at least a portion of a first side of the base member. The retaining apparatus includes a support member, multiple flexible finger members positioned proximate a periphery of the support member, and at least one wall member. The PCB has one or more components attached thereto. The support member of the retaining apparatus has a first side and a second side (e.g., a top side and an underside). Each finger member of the retaining apparatus extends away from the second side of the support member and has a restoring force (e.g., a spring force) toward the center of the support member. Each wall member of the retaining apparatus also extends away from the second side of the support member. The PCB is retained by and between the finger members of the retaining apparatus (e.g., by the restoring forces of the finger members). Each wall member of the retaining apparatus is sized and shaped to restrict deflection of at least one area of the PCB in the event that the PCB is subjected to at least one externally applied force (e.g., due to mechanical shock or otherwise).

Although the present disclosure illustrates and describes several exemplary embodiments for a structure-mountable electronic device assembly, the disclosure is, nevertheless, not intended to be limited to the details shown because various modifications and structural changes may be made to the disclosed embodiments without departing from the scope and range of equivalents of the appended claims. Additionally, well-known elements of the disclosed embodiments will not be described in detail or will be omitted so as not to obscure the relevant details of such embodiments.

Detailed exemplary embodiments of an electronic device assembly are disclosed herein; however, the disclosed embodiments are merely exemplary, and the assembly may be embodied in various forms. Therefore, specific structural and functional details disclosed herein are not to be interpreted as limiting, but merely as a basis for the claims and as a representative basis for teaching one of ordinary skill in the art to variously employ the claimed invention in exemplary embodiments. Further, the terms and phrases used herein are not intended to be limiting but rather are intended to provide an understandable description of the present disclosure.

The terminology used herein is for the purpose of describing particular embodiments only and is not intended to be limiting. The terms “a” or “an,” as used herein, mean one or more. The term “plurality,” as used herein, means two or more. The term “another,” as used herein, means at least a second or more. The terms “comprises,” includes,” “contains,” “has,” and their respective formatives, as used in the present disclosure and the appended claims, are intended to be open-ended or non-exhaustive (i.e., open language) and should be interpreted as if each was followed by the words “but is not limited to.” The terms “coupled” and “connected,” as used herein, mean connected directly or indirectly; permanently, semi-permanently, or temporarily; mechanically, integrally, electrically, logically, or operably; or in any other manner. The term “providing” is defined herein in its broadest sense (e.g., bringing/coming into physical existence, making available, and/or supplying to someone or something, in whole or in multiple parts at once or over a period of time).

As used in the present disclosure, unless otherwise specified, relationships indicated by terms such as “up,” “down,” “left,” “right,” “inside,” “outside,” “interior,” “exterior,” “front,” “back,” “head,” “tail,” “base,” “cover,” “top,” “bottom,” and so on, are azimuth or positional relationships based on the drawings or to identify elements or objects, and are only intended to facilitate the descriptions of the disclosed embodiments of the present disclosure, but not to indicate or imply that the elements or objects must have a specific azimuth, or be constructed or operated in the specific azimuth. Furthermore, terms such as “first,” “second,” “third,” and so on are only used for identification purposes and should not be construed as indicating or implying any relative importance or order.

As used in the present disclosure and the appended claims, the term “longitudinal” should be understood to mean in a direction corresponding to an elongated direction of an object.

The terms “about,” “substantially,” “generally,” or “approximately” apply to all numeric values, whether explicitly indicated or not. When used expressly or impliedly in the present disclosure and the appended claims, such terms refer to a range of values, quantities, features, and/or functionality that one of ordinary skill in the art would consider equivalent to the recited values, quantities, features, and/or functionality (e.g., would provide an equivalent result). In many instances these terms may include numbers that are rounded to the nearest significant figure. Those skilled in the art will readily understand the specific meanings of the above-mentioned terms in the embodiments of the present disclosure according to the specific circumstances.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and explain various principles and advantages all in accordance with the present disclosure. Some of the elements and features disclosed herein may be viewable in one or more of the figures, but not necessarily in all the figures. The figures of the drawings are not drawn to scale.

FIG. 1 is an exploded view of an electronic device assembly, in accordance with exemplary embodiments of the present disclosure.

FIG. 2 is a bottom view of an exemplary mounting bracket for use in the electronic device assembly of FIG. 1.

FIG. 3 is a bottom view of the electronic device assembly of FIG. 1 in assembled form.

FIG. 4 is an elevational view of an exemplary electronic device assembly as mounted in an exemplary manner to a vertical (e.g., decorative) lighting fixture with a partial cut-away view of a base of the lighting fixture to show an optional threaded external surface of the electronic device assembly, in accordance with some alternative embodiments of the present disclosure.

FIG. 5 is a perspective view of an electronic device assembly as mounted in an exemplary manner to a support structure, such as a cobra head luminaire, in accordance with some exemplary embodiments of the present disclosure.

FIG. 6 illustrates an exploded perspective view of an exemplary printed circuit board (PCB) module for an electronic device of the electronic device assembly of FIG. 1 and a top perspective view of the PCB retaining apparatus of the PCB module, in accordance with exemplary embodiments of the present disclosure.

FIG. 7 illustrates, in PCB layout and block diagram form, a top view of an exemplary PCB for the PCB module illustrated in FIG. 6.

FIG. 8 is a top view of the exemplary PCB retaining apparatus of FIG. 6.

FIG. 9 is a bottom view of the exemplary PCB retaining apparatus of FIG. 6.

FIG. 10 is a top view of the exemplary PCB retaining apparatus of FIG. 6 as attached to a base housing member of an exemplary electronic device forming part of the electronic device assembly of FIG. 1.

FIG. 11 is a perspective view of a partially assembled electronic device with a partially or fully translucent cover housing member and the top section of the cover housing member excluded for clarity purposes, in accordance with other exemplary embodiments of the present disclosure.

FIG. 12 is a cross-sectional view of the electronic device of FIG. 11 with the top section of the cover housing member included.

FIG. 13 is an enlarged cutaway view of a portion of an interior surface of the electronic device of FIG. 11 illustrating exemplary facets included on the interior surface.

FIG. 14 is an electrical block diagram of a lighting control device including a light sensing system and a power metering circuit, in accordance with further exemplary embodiments of the present disclosure.

FIG. 15 is an electrical block diagram of an exemplary power metering circuit of the lighting control device of FIG. 14.

FIG. 16 is a bottom perspective view of the electronic device assembly of FIG. 1 in assembled form.

FIG. 17 is a bottom plan view of the assembled electronic device assembly of FIG. 16.

### DETAILED DESCRIPTION

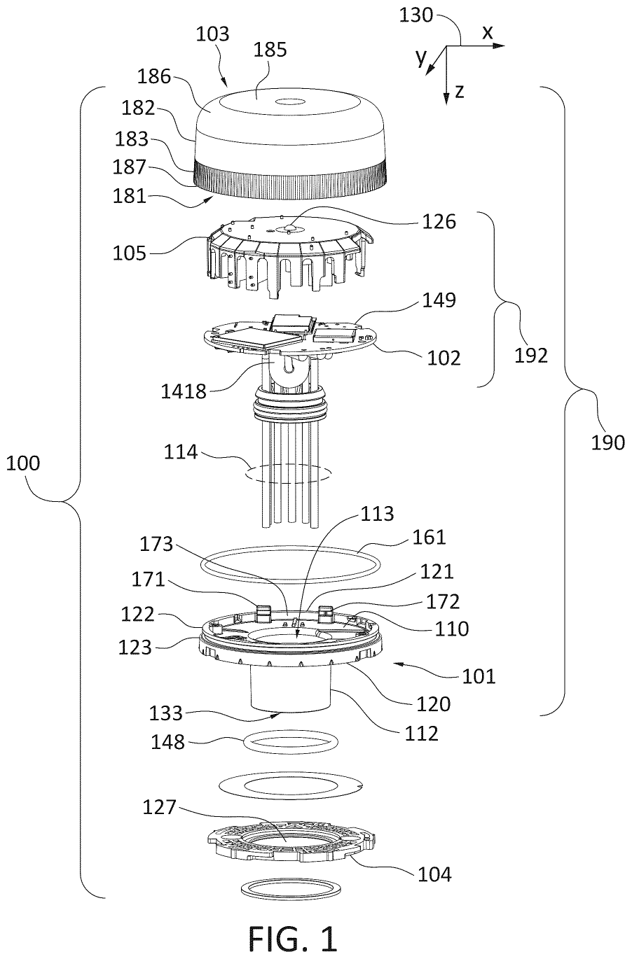

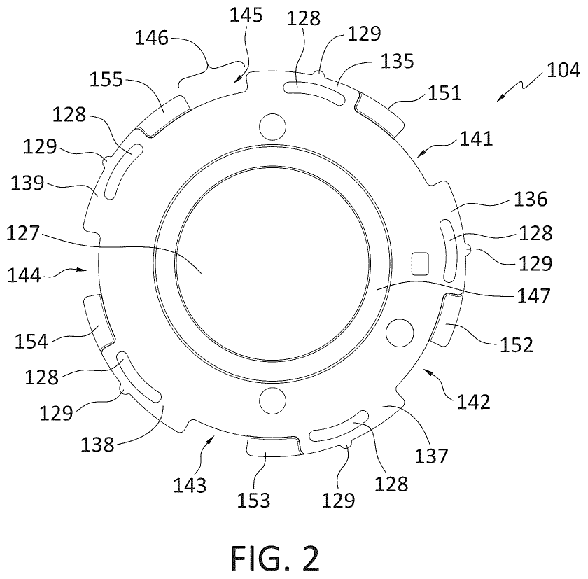

FIG. 1 is an exploded view of an electronic device assembly, in accordance with exemplary embodiments of the present disclosure. The electronic device assembly 100 includes an electronic device 190 and a mounting bracket 104. The electronic device 190 includes a first or base housing member 101, a printed circuit board (PCB) 102 with a plurality of electrical and optionally other components arranged and configured to enable the electronic device 190 to perform its intended function, and a second or cover housing member 103. The base housing member 101 may be positioned to form the bottom housing member of the electronic device 190 and the cover housing member 103 may be positioned to form the top housing member of the electronic device 190, or vice versa. The mounting bracket 104 is described in more detail below with respect to FIG. 2.

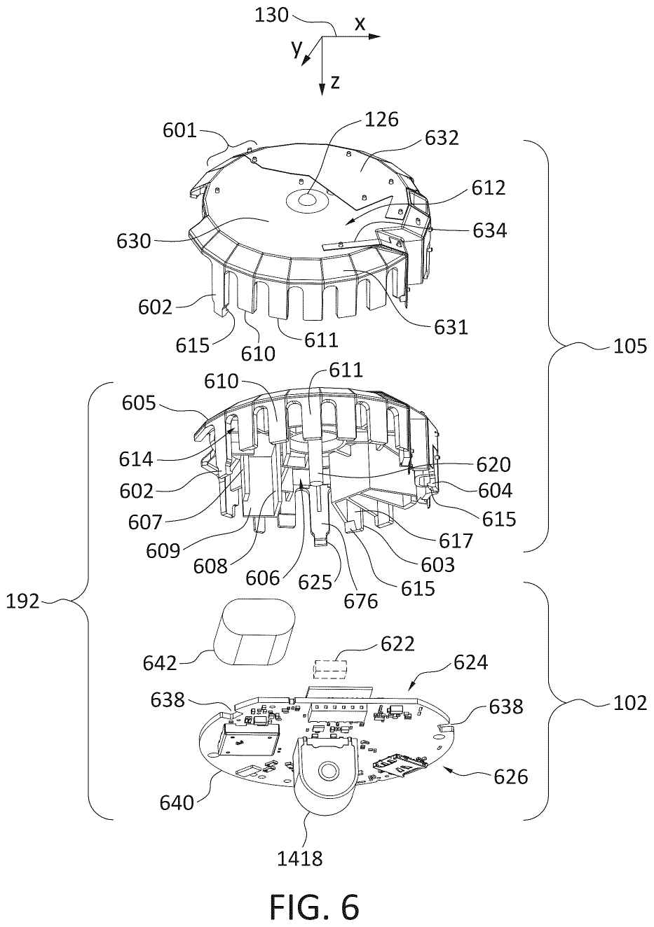

According to some embodiments, the electronic device 190 further includes a PCB retaining apparatus 105, which together with the PCB 102 and its associated components 149 form a PCB module 192. As illustrated in more detail in FIGS. 6, 8, and 9, the PCB retaining apparatus 105, when included, includes a support member 601 having a first side 612 and an opposing second side 614, a plurality of flexible finger members 602-604 (three numbered for illustrative purposes but two or more could be used) positioned proximate a periphery 605 of the support member 601, and at least one wall member 606-611, 902-920 (several numbered for illustrative purposes but one or more may be used depending on several factors, such as PCB size, PCB layout, PCB component types and quantities, configuration of the electronic device, and so forth). Each finger member 602-604 extends away from the support member 601 in a direction generally opposite the first side 612 of the support member 601 and has a restoring force toward a center of the second side 614 of the support member 601 (or, more generally, toward a center of the support member 601). The restoring forces of the finger members 602-604 cause inside surfaces of the finger members 602-604 to engage peripheral areas 640 of the PCB 102 (e.g., at least the edges) to retain the PCB 102 in place after it has been positioned between the finger members 602-604. Each wall member 606-611, 902-920 extends away from the second side 614 of the support member 601 and is sized and shaped to restrict deflection of at least one area of the PCB 102 responsive to one or more externally applied forces after the PCB 102 is positioned between the finger members 602-604. For example, the wall members 606-611, 902-920 are configured to at least restrict deflections of one or more areas of the PCB 102 containing electrical or mechanical components 149, 622, 702, 704, 1444 of the PCB 102. Advantageously, the retaining apparatus 105 provides a robust structure to help minimize shock and potential damage to the PCB 102 and its components in the event the electronic device assembly 100 is exposed to one or more undesirable external forces, such as impacts from being dropped or having objects or projectiles contacting it.

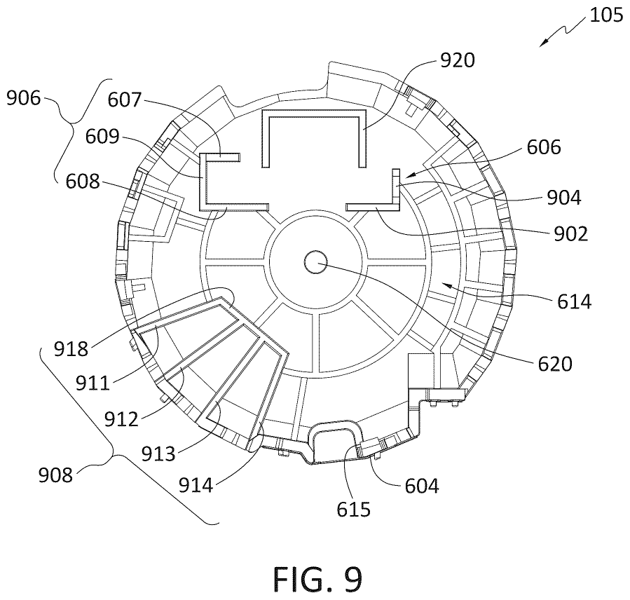

As illustrated in FIGS. 6 and 9, the wall members 606-611 may be individually or collectively configured into various shapes as necessary to restrict deflections in selected areas of the PCB 102. For example, wall member 606 may generally form an “L shape” with a long member 902 and a short member 904. Additionally or alternatively, wall members 607-609 may form a multi-wall member 906 configured generally in a “C shape.” Further, another multi-wall member 908 may include a base wall member 918 and four radial wall members 911-914. Still further, another wall member 920 may be configured generally in a “U shape.” The quantity of anti-deflection wall members and their configurations will depend on the configuration and component locations of the particular PCB 102.

The cover housing member 103 is illustrated in FIG. 1 as being generally dome-shaped (e.g., a compound dome, a geodesic dome, an oval dome, or a generally semi-spherical shape) but may be shaped otherwise (e.g., paraboloid, parallelepiped, conical, etc.) with an open bottom 181, one or more sidewalls (which may have an optional upper sidewall portion 182 and an optional lower sidewall portion 183), and a top 185 (which may be at least partially translucent). Interior surfaces of the sidewall(s) and the top 185 form an interior chamber that accommodates at least the PCB module 192. In some embodiments, the upper sidewall portion 182 is also translucent.

According to some exemplary embodiments, the exterior surfaces 186 of the top 185 and the upper sidewall portion 182 are generally smooth while the external surface of the lower sidewall portion 183 is irregular, such as faceted, grooved, abrasive, rough, wavy, or curved. When so configured, the generally irregular exterior surface 187 of the lower sidewall portion 183 provides an enhanced gripping surface for twisting or rotating the electronic device 190 during mounting or dismounting of the electronic device 190 to or from the mounting bracket 104 at the time of installation or removal, as appropriate.

The base housing member 101 has a first side 110 (e.g., a top side) and an opposing second side 111 (e.g., a bottom side or underside). According to some exemplary embodiments, the top side 110 of the base housing member 101 includes at least one sidewall section 121 along an outer periphery thereof, wherein an outside surface 122 of the at least one sidewall section 121 defines a channel 123 configured to receive a seal, such as a gasket, an O-ring 161, or a sealant, at least partially therein. The at least one sidewall section 121 may be a single continuous sidewall, a series of connected sidewall sections, or a set of spaced sidewall sections with gaps in between.

According to some embodiments, the channel 123, when included, is configured to beneficially receive and retain the seal therein. The seal helps mitigate the likelihood that moisture will enter the electronic device 190 or reach the PCB 102 or its components located inside the chamber of the cover housing member 103, such as during inclement weather (such as rain, sleet, or snow, for example). When used, the seal preferably fits snugly against the interior surface of the sidewall of the cover housing member 103, such as at or about where the upper sidewall portion 182 meets the lower sidewall portion 183.

According to additional or alternative embodiments, one or more retaining clips 171, 172 (two shown for illustrative purposes in FIG. 1) are positioned on or along an inside surface 173 of the at least one sidewall section 121 to retain at least a portion of the PCB 102. In such embodiments, one or more peripheral areas of the PCB 102 are positioned into the clips 171, 172 (e.g., pressed or slid into the clips 171, 172) such that the PCB 102 is secured by the clips 171, 172 to, for example, a ledge along the at least one sidewall section 121 of the first side 110 of the base housing member 101. Positioning peripheral areas of the PCB 102 on a ledge allows the PCB 102 to be double-sided, having components on both sides. Alternatively, where the PCB 102 has components on only one side (e.g., the top side), the retaining clips 171, 172 and the PCB 102 may be positioned further down the inside surface(s) 173 of the at least one sidewall section 121 and closer to an aperture 113 defined by and through the base housing member 101.

According to some embodiments as illustrated in FIG. 1, the electronic device 190 further includes a conduit 112 extending from the second side 111 of the base housing member 101. When included, the conduit 112 defines a passageway 133 in fluid communication with the aperture 113 defined by and passing through the base housing member 101. The conduit passageway 133 is sized and shaped to allow wires and/or conductors 114, such as the line conductor of an alternating current (AC) power source, the AC line conductor of a lamp driver, one or more ground conductors, direct current (DC) power conductors, and control signal wires, just to name a few, to be fed through it to and/or from the PCB 102. The shape of the conduit 112 is also such that it passes through a central opening 127 in the mounting bracket 104. To provide water sealing, the passageway 133 may be filled with epoxy after the wires are threaded through the passageway 133 or the wires 114 may be secured in a plug that has its own O-ring or other seal to snugly fit into the passageway 133 to provide a water-tight seal.

In other exemplary embodiments, the bottom side 111 of the base housing member 101 is configured to be twist-lockable with the mounting bracket 104, as described in more detail below with respect to FIGS. 2, 3, 16, and 17. In these embodiments, the mounting bracket 104 is first attached to a support structure, such as, for example, a utility pole, a streetlight luminaire or other lighting fixture, a wall of a building, or any other structure having electrical power accessible from it, and then the electronic device 190 is secured in a twist-lock manner to the mounting bracket 104.

According to some exemplary embodiments, the cover housing member 103 is at least partially translucent to allow ambient light impinging on the exterior surface of the cover housing member 103 to pass through the translucent portion of the cover housing member 103 to either a light sensor 622 (e.g., a photosensor) on the PCB 102 or an entrance or input 126 to an optional light guide 620 of or coupled to the PCB retaining apparatus 105 (described in more detail below with respect to FIG. 6), which light guide 620 directs the light (or at least some of it) to the light sensor 622 on the PCB 102. In one exemplary embodiment in which the electronic device 190 is a lighting control apparatus (or a lighting control device thereof) or otherwise includes lighting control functionality, the light sensor 622 provides an output signal corresponding to the amount of incident light detected, which output signal is used by a processor of the electronic device 190 to generate lighting control signals for a driver of a light source (e.g., one or more LED panels of a lighting fixture). For example, when the output signal of the light sensor 622 indicates the luminosity of the incident light is at or above a predetermined threshold, the processor will not produce a control signal that causes the driver to turn on the light source or, if the light source is already on, the processor will produce a control signal that causes the driver to turn off the light source. On the other hand, when the output signal of the light sensor 622 indicates the luminosity of the incident light is below the predetermined threshold, the processor will not produce a control signal that causes the driver to turn off the light source or, if the light source is already off, will produce a control signal that causes the driver to turn on the light source.

FIG. 2 illustrates a bottom view of an exemplary embodiment of the mounting bracket 104. The exemplary mounting bracket 104 defines a plurality of gaps 141-145 and includes a plurality of notches 151-155 along an outer periphery portion of the bracket 104. As may be better understood with reference to FIGS. 2, 16, and 17, each notch 151-155 is adjacent to a respective gap 141-145, and a width 146 of each gap 141-145 permits passage of a respective tab member 131a-131e on the bottom side 111 of the base housing member 101. Each notch 151-155 of the mounting bracket 104 rests upon a respective tab member 131a-131e of the base housing member 101 after the tab member 131a-131e has passed through the respective gap 141-145 adjacent to the notch 151-155 and the base housing member 101 or the entire electronic device 190 has been rotated so as to position each tab member 131a-131e over its associated notch 151-155 of the mounting bracket 104.

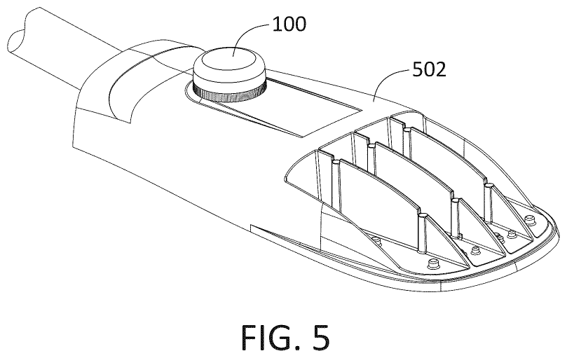

The electronic device assembly 100 may be securely mounted to a support structure, such as a utility pole, a streetlight pole, a streetlight luminaire, or other structure from which electrical power is accessible. To do so, the mounting bracket 104 is first mounted to the support structure. Such mounting may be performed using one or more fasteners or by other means. For example, referring to FIG. 5, where the electronic device assembly 100 is intended for mounting to a streetlight luminaire 502 that has a National Electrical Manufacturers Association (NEMA) socket in compliance with the American National Standards Institute (ANSI) C136 series of standards, the screws that would otherwise be used to secure the NEMA socket to the luminaire may be instead used to secure the mounting bracket 104 to the luminaire at the same locations as the NEMA socket would be normally mounted. Alternatively, the electronic device assembly 100 may be mounted to a streetlight luminaire 502 at the location where an external connector in compliance with another roadway lighting connection standard, such the Zhaga Book 18 standard, would otherwise be connected.

After the mounting bracket 104 has been mounted to the support structure, the base housing member 101 of the electronic device 190 is secured to the mounting bracket 104. The base housing member 101 may be attached to the mounting bracket 104 by, for example, aligning the tab members 131a-131e of the base housing member 101 with the gaps 141-145 of the mounting bracket 104, moving the base housing member 101 toward the mounting bracket 104 such that tab members 131a-131e pass through the gaps 141-145 in the mounting bracket 104, and rotating the base housing member 101 or the entire electronic device 190 relative to the mounting bracket 104 until each notch 151-155 is positioned over and/or rests upon a respective tab member 131a-131e of the base housing member 101. According to some embodiments, the base housing member 101 or the entire electronic device 190 may be rotated relative to the mounting bracket 104 until the leading side edges of the tab members 131a-131e of the base housing member 101 engage the closed ends or edges of the notches 151-155 of the mounting bracket 104. According to some embodiments, the widths of the gaps 141-145 of the mounting bracket 104 and the widths of the tab members 131a-131e of the base housing member 101 may be mutually varied (as opposed to all being the same) so as to form a keyed system for mounting the base housing member 101 to the mounting bracket 104, particularly where orientation of the electronic device 190 as mounted to the structure is critical to operation of the electronic device 190. In general, the electronic device assembly 100 is configured to facilitate a simple and repeatable process of mounting the assembly 100 to a structure, especially under circumstances in which installers may be wearing gloves and operating in a bucket truck for safety purposes.

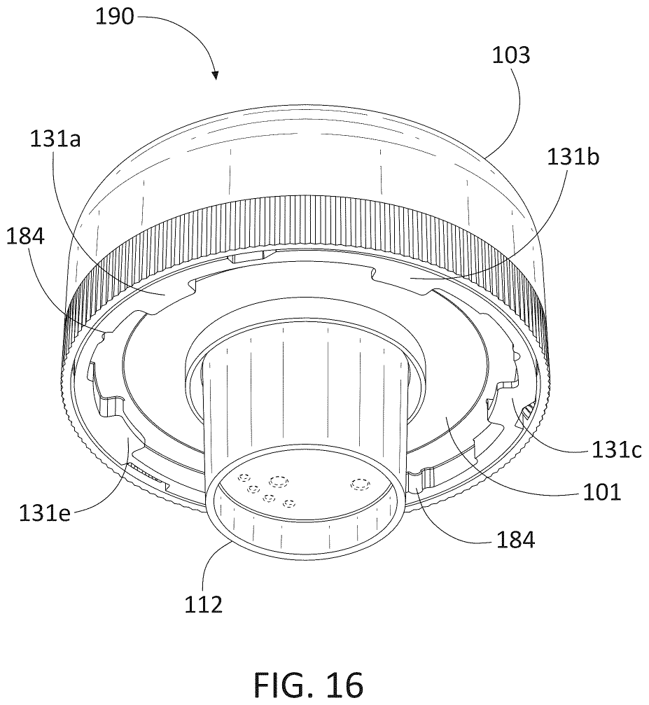

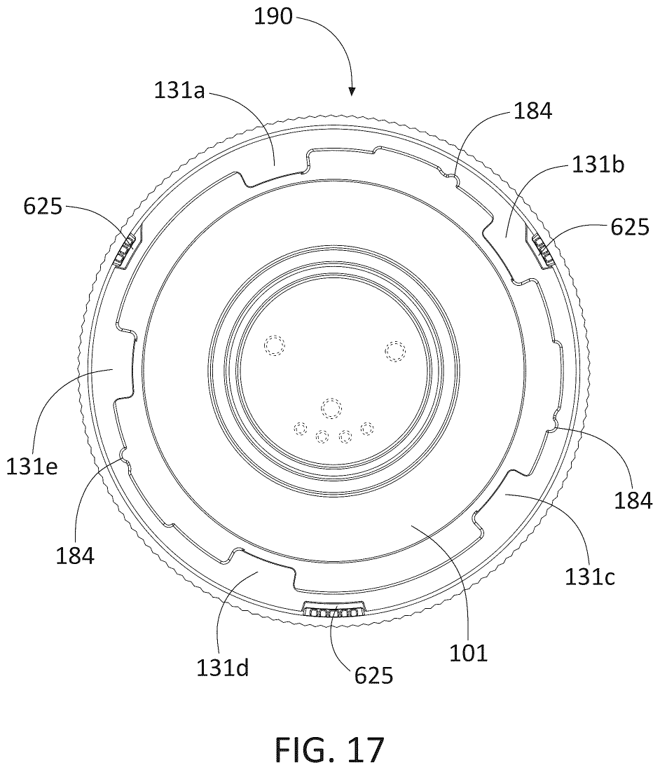

According to some embodiments of the present disclosure, the mounting bracket 104 may be a low profile disc or flat circular structure with a central opening 127 configured to receive the conduit 112 of the electronic device 190 through which wires or conductors 114 are routed. Additionally, the mounting bracket 104 may include a grooved or recessed area 147 proximate the central opening 127 to receive a seal (e.g., an O-ring 148, gasket, or adhesive) positioned between the underside 111 of the base housing member 101 and the mounting bracket 104. The outer periphery of the mounting bracket 104 may also include arched sections 135-139 adjacent to the notches 151-155, where each arched section 135-139 defines or includes a slotted aperture 128 and an outer protrusion 129. During mounting of the electronic device 190 to the mounting bracket 104 or removal of the electronic device 190 from the mounting bracket 104, the slotted apertures 128 allow the protrusions 129 of the mounting bracket 104, when included, to deflect slightly inward during rotation of the electronic device 190 or its base housing member 101. Referring also to FIGS. 16 and 17, the protrusions 129 then return to a non-deflected or normal position to lock or mate into or with complementarily shaped recesses 184 on the inside surface(s) of the sidewall section(s) 120 on the bottom side 111 of the base housing member 101.

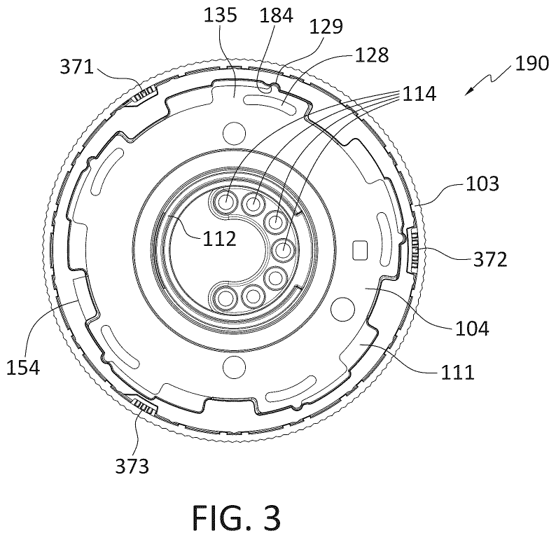

The exemplary electronic device 190 and the exemplary electronic device assembly 100 are shown in assembled forms from various viewpoints in FIGS. 3. 16, and 17. For example, FIG. 3 is a bottom plan view of the assembled electronic device assembly 100, FIG. 16 is a bottom perspective view of the assembled electronic device 190, and FIG. 17 is a bottom plan view of the assembled electronic device 190. According to some embodiments, as illustrated in FIG. 3, the bottom side 111 of base housing member 101 is mounted to the mounting bracket 104 so as to maintain a low profile along a Z-axis with reference to the 3D axis system 130 shown in FIG. 1.

In some embodiments as illustrated in FIGS. 16 and 17, the bottom side 111 of the base housing member 101 includes a plurality of spaced apart tab members 131a-131e extending from the inside surface of the sidewall section(s) 120 toward the center of the bottom side 111 of the base housing member 101 or, more generally, toward the center of the base housing member 101. Additionally or alternatively, the inside surface(s) of the sidewall sections(s) 120 also includes recesses 184 that are sized and shaped to receive protrusions 129 of the mounting bracket 104 when the electronic device 190 is rotatably secured to the mounting bracket 104.

According to other embodiments as illustrated in FIG. 3, the cover housing member 103 may include a plurality of optional spaced apart retaining clips 371-373 (three shown for illustration) along a bottom edge thereof. The retaining clips 371-373 include tabs or lips that extend toward the center of the cover housing member 103 and engage a bottom edge of the base housing member's sidewall 120 or bottom edges of one or more of the base housing member's sidewall sections (e.g., where the sidewall 120 is not continuous) when the cover housing member 103 is positioned over the PCB 102 and pushed onto the base housing member 101. When included, the retaining clips 371-373 have restoring forces that cause the cover housing member 103 to lock to the base housing member 101.

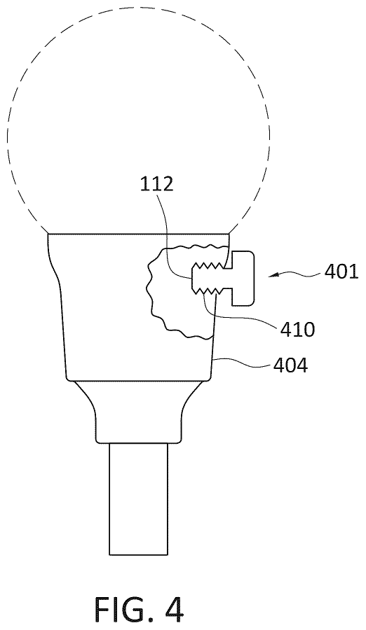

FIG. 4 illustrates an alternative exemplary electronic device assembly 401 as mounted in an exemplary manner to a vertical lighting fixture and includes a partial cut-away view of a base 404 of the lighting fixture to show an optional threaded external surface 410 of the electronic device assembly 401, in accordance with some alternative embodiments of the present disclosure. In this case, the electronic device 401 is substantially similar to the electronic device 190 described above, except that the conduit 112 is threaded (i.e., includes threads 410) on an exterior surface thereof. The support structure 404 to which the electronic device 401 is attached may have mating threads along an interior surface thereof at the electronic device attachment point. For these embodiments, the electronic device assembly 401 includes the electronic device and the threads 410 of the conduit instead of the electronic device 190 and the mounting bracket 104.

In some exemplary embodiments, the electronic device 190 includes a controller or other processor and provides Internet of Things (IoT) functionality. The IoT functionality can include power metering, lighting control, and asset management, as well as transmitting associated data via wireless communication to a remote computer system or server to facilitate reporting and alerting. In one exemplary embodiment, the electronic device 190 is a networked lighting controller in a smart lighting system.

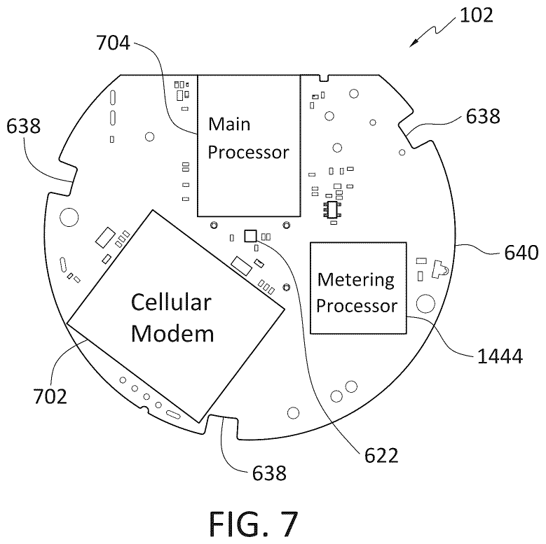

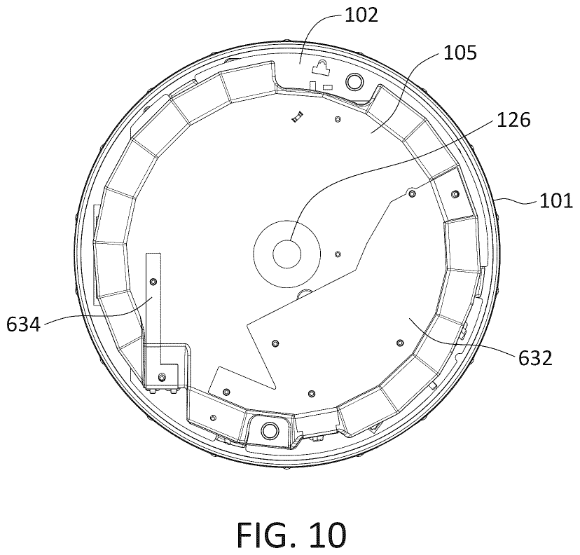

FIG. 6 illustrates an exploded bottom perspective view of the PCB module 192 for the electronic device 190 of the electronic device assembly 100 of FIG. 1 and a top perspective view of the PCB retaining apparatus 105 of the PCB module 192, in accordance with exemplary embodiments of the present disclosure. According to such embodiments and referring also to FIGS. 7-10, the retaining apparatus 105 includes a support member 601, a plurality of flexible finger members 602-604 (three shown for illustration) positioned proximate a periphery 605 of the support member 601, and at least one wall member 606-611 (six identified by reference numerals for illustration). The support member 601 has a first side 612 (e.g., top side) and an opposing second side 614 (e.g., bottom side or underside). Each finger member 602-604 extends away from the support member 601 in a direction generally opposite the top side 612 of the support member 601 and has a restoring force toward a center of the bottom side 614 of the support member 601 or, more generally, toward a center of the support member 601. The one or more wall members 606-611 also extend away from the bottom side 614 of the support member 601, such as in the direction opposite the first side 612 of the support member 601. The wall members 606-611 are sized and shaped to restrict deflection of at least one area of the PCB 102 responsive to an externally applied force after the PCB 102 is positioned (e.g., inserted, push fit, or otherwise installed or assembled) between the finger members 602-604.

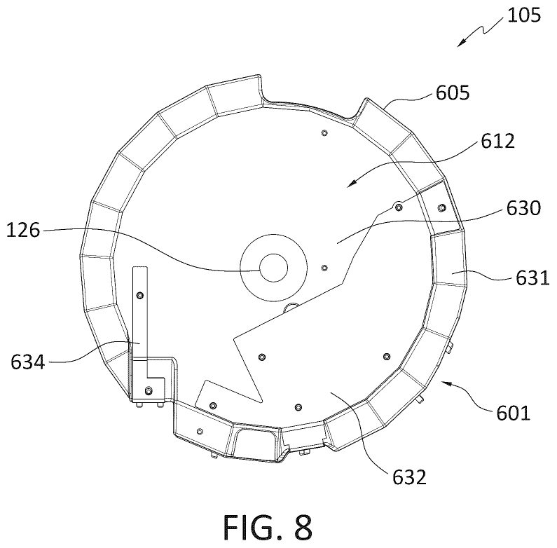

In one exemplary embodiment and referring also to FIG. 8, the support member 601 includes a substantially flat section 630 and an angled section 631 joined to the substantially flat section 630, where the angled section 631 extends to the periphery 605 of the support member 601. In some embodiments, the flat section 630 of the support member 601 has a generally circular shape as illustrated in FIG. 6. However, persons of ordinary skill in the art will readily recognize and appreciate that the flat section 630 may be any other desired shape depending on the geometric design of the PCB retaining apparatus 105, including oval, oblong, square, rectangular, pentagonal, hexagonal, octagonal, and the like.

According to some exemplary embodiments, the PCB retaining apparatus 105 (or at least the support member 601, the finger members 602-604 and the one or more wall members 606-611) is formed as a single molded part or component. Beneficially, a single molded component can provide a mass-producible and cost-effective design. When formed as a molded component, the PCB retaining apparatus 105 may be fabricated from a plastic that provides structural integrity while adding desired flexibility. Some exemplary materials from which to mold the PCB retaining apparatus 105 include acrylonitrile butadiene styrene (ABS), polycarbonate, a polycarbonate and ABS blend, polyphenylene oxide, polyphenylene ether, polybutylene terephthalate, polyamide, polymethyl methacrylate, styrene ethylene butadiene styrene, and acrylic.

In some exemplary embodiments, the support member 601 (e.g., the flat section 630 thereof) defines an aperture located at least partially above an expected location of a light sensor 622 secured to the PCB 102. When included, the aperture is sized and shaped to accommodate and partially receive a light guide 620 therethrough to direct incident light toward the light sensor 622. The light sensor 622 (shown in phantom in FIG. 6) is surface mounted or otherwise secured to the top side 624 of the PCB 102, for example. An entrance or input 126 of the light guide 620 may be located on the top side 612 of the support member 601 of the PCB retaining apparatus 105. In alternative embodiments, the light guide 620 may be integrated with and formed as part of the PCB retaining apparatus 105. In some embodiments, the light guide 620 extends from the underside 614 of the PCB retaining apparatus 105 toward the top side 624 of the PCB 102 such that the light guide's output is positioned just above (e.g., 2-25 mm above) the light sensor 622 on the PCB 102.

In further exemplary embodiments, some or all the finger members 602-604 include tabs 615 on inward-facing sides 617 of the finger members 602-604. When included, the tabs 615 provide support for the PCB 102 upon positioning of the PCB 102 between the finger members 602-604 or equivalently upon positioning of the finger members 602-604 about the PCB 102. In one such embodiment, each finger member 602-604 includes a tab 615 on its inward-facing side 617 for enhanced connections to and support of the PCB 102. In an alternative embodiment, at least three finger members 602-604 include tabs 615 on their inward-facing sides 617.

In some exemplary embodiments, the PCB 102 further includes an outer periphery or outer peripheral areas 640 defining one or more recesses 638 (two shown for illustration in FIG. 6 and three shown for illustration in FIG. 7) that are complementarily configured to allow one or more longer finger members 676 with inside-facing tabs 625 and restoring forces toward the center of the PCB retaining apparatus 105 to pass through the spaces created by the recesses 638 and engage an underside 626 of the PCB 102 with the tabs 625. When properly assembled, each longer finger member 676 resides partially in a respective recess 638, and each tab 625 contacts the bottom side 626 of PCB 102 for an enhanced connection and support.

In some exemplary embodiments, multiple wall members 607-611 may be used to restrict deflection of the PCB 102 near larger PCB components, such as larger integrated circuits 702, 704, 1444, capacitors 642, inductors, transformers, toroids, and so forth. In such cases, the walls 607-611 are positioned adjacent to and/or just above the component to minimize and restrict unwanted deflection of the area or areas of the PCB 102 at or to which the components 642, 702, 704, 1444 are attached (e.g., soldered) in the event of an undesirable externally applied force or mechanical shock, for example.

According to other exemplary embodiments in which the electronic device 192 transmits or receives information wirelessly, such as a through a cellular modem 702 or another wireless communication circuit, or receives GNSS signals (e.g., GPS signals) to facilitate location determination, the electronic device 192 includes or more antennas 632, 634 for such purposes. According to the exemplary embodiments illustrated in FIGS. 6, 8, and 10, the antennas 632, 634 are positioned (e.g., disposed or deposited on, attached to, secured to, and the like) at least partially on the top side 612 of the support member 601. Alternatively, the antennas 632, 634 may be positioned wholly or partially on the bottom side 614 of the support member 601. Further, depending on how grounding is arranged in the electronic device 192, a portion of each antenna 632, 634 may be disposed on one or more of the longer fingers 676 (or posts) to allow the antenna 632, 634 to be electrically connected to a ground plane on the top side 624 or the bottom side 626 of the PCB 102, for example. According to one exemplary embodiment, antenna 632 supports the cellular modem 702 illustrated in block form in FIG. 7 in connection with cellular communications, such as LTE or 5G communications, and antenna 634 supports reception of GPS signals for processing by the cellular modem 702 (where such modem 702 is GPS-enabled) or the electronic device's main processor 704, as also illustrated in block form in FIG. 7. As should be understood by those skilled in the art, other signaling protocols may be used and supported by the antennas 632, 634 depending on the application or use case. Additionally, multiple antennas may be used for a single purpose (e.g., diversity antennas or multiple input multiple output (MIMO) antennas may be used for cellular communications).

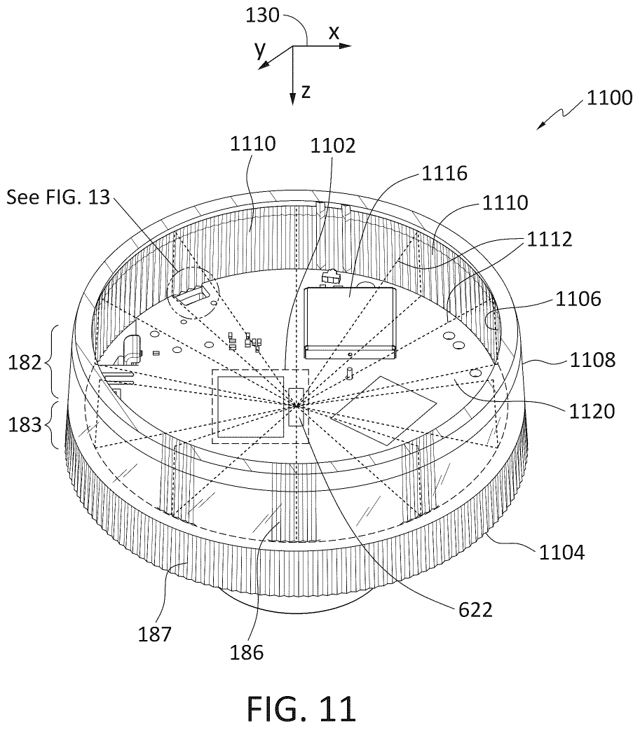

FIGS. 11-13 illustrate various views of an electronic device 1100 in accordance with further alternative exemplary embodiments of the present disclosure. The electronic device 1100 includes several elements of the electronic device 100 of FIG. 1 and may include all the elements of such electronic device 100, except with modifications to the cover housing member 103 as described in more detail below.

According to the alternative embodiments illustrated in FIGS. 11-13, the electronic device 1100 includes a light sensing system 1102 (shown generally in block form in FIG. 11) and an at least partially translucent housing member 1104 positioned over at least the light sensing system 1102 and, more preferably, over the entire PCB 1120 (e.g., PCB 102) containing the light sensing system 1102. The housing member 1104 is shown without its top in FIG. 11 merely to aid the relevant description of the electronic device 1100. Similar to the cover housing member 103 illustrated in FIG. 1, the housing member 1104 may be generally dome-shaped (e.g., a compound dome, a geodesic dome, an oval dome, or a generally semi-spherical shape) or shaped otherwise (e.g., paraboloid, parallelepiped, conical, etc.) with an open bottom, one or more at least partially translucent sidewalls, and an at least partially translucent top (not shown). Thus, the housing member 1104 defines a chamber within its interior to house the PCB 1120 and its components (or at least the components attached to the top side of the PCB 1120), including the components of the light sensing system 1102. In some embodiments, the sidewall(s) has a translucent upper sidewall portion 182 and an optional lower sidewall portion 183, which may also be translucent. The lower sidewall portion 183 may have an irregular exterior surface to improve grip when mounting the electronic device 1100 to a mounting bracket 104, for example.

The sidewall(s) of the electronic device 1100 have an interior surface 1106 and an exterior surface 1108. In the embodiments illustrated in FIGS. 11-13, the interior surface 1106 includes a plurality of facets 1110 configured to direct light impinging on the exterior surface 1108 of the translucent section of the sidewall(s) (e.g., the upper sidewall portion 182 of the housing member 1104) toward the light sensing system 1102 or a portion of it, such as the light sensor 622 or the entrance or input 126 to a light guide 620 or light pipe (e.g., where the PCB 1120 is retained by a retaining apparatus 105 and the retaining apparatus 105 includes, uses, or accommodates the light guide 620). Advantageously, the facets 1110 are designed and configured to create a prismatic or Fresnel lens effect that focuses/converges light rays 1112 passing through the translucent upper sidewall portion 182 of the housing member 1104 to a predetermined or desired target or location within the chamber of the housing member 1104, such as toward the light sensing system 1102 or the input 126 to a light guide 620 having its output positioned just above (e.g., 2-25 mm above) the light sensor 622, for example.

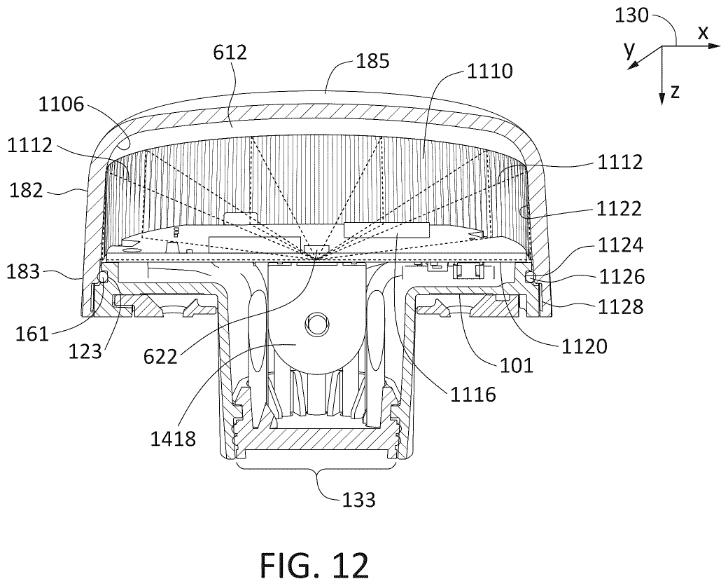

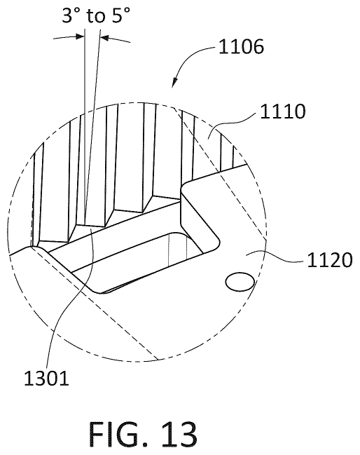

The housing member 1104 illustrated in FIGS. 11-13 may be the cover housing member 103 of the electronic device 100 shown in FIG. 1, with an interior surface 1106 including facets 1110 as illustrated in FIGS. 11-13. As shown in enlarged form in FIG. 13, the facets 1110 of the housing member's interior surface 1106 are arranged in pairs in some embodiments and together with a respective translucent portion of the exterior surface 1108 forms a triangular prism that directs the impinging light toward its intended target (e.g., the light sensor 622 or the light guide input 126). In alternative embodiments, the facets 1110 are integrated into the interior surface 1106 of the housing member 1104 but may alternatively be formed into a separate film or covering that is adhered to the interior surface 1106 of the housing member 1104. In further embodiments, the facets 1110 are evenly distributed along the interior surface 1106 of the housing member 1104, such as illustrated in FIGS. 11 and 12. In other embodiments, each facet 1110 is angled relative to a reference axis, such as an axis substantially perpendicular to the PCB 1120 when the electronic device 1100 is fully assembled, so as to more accurately or effectively direct light impinging on the translucent exterior surface 1108 to the location of the intended target (e.g., the light sensor 622 or the input 126 to the light pipe 620). In some exemplary embodiments, such as illustrated in FIG. 13, each facet 1110 is angled in the range of approximately three degrees (3°) to approximately five degrees (5°) relative to a respective reference axis and toward the center of the electronic device 1100 (e.g., relative to the Z-axis in the reference 3D axis system 130 shown in FIGS. 1 and 12) for a more consistent and enhanced focus of impending light on the desired target. In further exemplary embodiments, the exterior surface 1108 of the housing member 1100, or at least the exterior surface of the upper housing portion 182, is smooth and devoid of any facets. Where the electronic device 1100 is intended for use in outdoor environments and, more specifically, is a lighting control device, a smooth exterior surface 1108 reduces the adherence of debris to the exterior surface 1108, which could affect operation of the light sensing system 1102 by preventing light from entering one or more translucent areas of the housing member's exterior surface 1108.

In some embodiments, the electronic device 1100 includes a processor 1116 (e.g., main processor 704) coupled to the light sensing system 1102. The processor 1116 is operable to, among other things, generate a lighting control signal responsive to receipt of a light sensing signal from the light sensing system 1102. The lighting control signal may be communicated to and be usable by a lamp driver of a lamp, such as an LED driver of one or more LED modules in an outdoor lighting fixture (e.g., a streetlight). For example, the lighting control signal may instruct the lamp driver to turn on the lamp, dim the lamp, or turn off the lamp.

In other embodiments, the electronic device 1100 includes a second housing member, such as the base housing member 101 of the electronic device 190 described above with respect to FIGS. 1-10. In such embodiments, the PCB 1120 is positioned upon at least a portion of the first side 110 of the base housing member 101, such as a lip or ledge of the base housing member 101, especially where the PCB 1120 has components mounted or attached to both of its sides.

In further exemplary embodiments, the electronic device 1100 includes the PCB retaining apparatus 105 (and optionally its light guide 620), as well as various other components and elements of the electronic device 190 of FIG. 1. Such components and elements are described in detail above with respect to FIGS. 1-10 and will not be repeated here for brevity.

In some exemplary embodiments in which the electronic device 1100 includes the PCB retaining apparatus 105, the top side 612 of the support member 601 is configured and strategically located within the chamber defined by the housing member 1104 such that light impinging on the exterior surface 1108 in the upper sidewall portion 182 can be directed by the facets 1110 to the input 126 of the light pipe 620 and thereby to the light sensor 622. Advantageously, such a structure and strategic placement permits the directed light rays 1112 to be substantially free from interference in reaching the light guide input 126, thereby contributing to the efficiency of the light sensing system 1102.

According to some other alternative embodiments as illustrated in FIG. 12, the interior surface 1106 of the housing member 1104 may include several functional sections 1122-1128. For example, one section 1122 may include the facets 1110. Another section 1124 may be adjacent to the PCB 1120. A third section 1126 may be adjacent to the channel 123 containing the seal (e.g., the O-ring 161). The last section 1128 may be adjacent to the periphery of the base housing member 101. In one embodiment, three interior surface sections 1124-1128 are configured to substantially complement the mechanical structures of the adjacent areas of the PCB 1120, the seal channel 123 or associated sidewall of the base housing member 101, and the periphery of the base housing member 101 to provide a snug and secure fit and an enhanced interface after the housing member 1104 is assembled over the PCB 1120 and at least part of the base housing member 101.

FIG. 13 illustrates, in enlarged form, a section of the interior surface 1106 of the cover housing member 1104 of the electronic device 1100 to more clearly show exemplary positioning of the interior surface facets 1110 relative to the PCB 1120 and an edge or lip 1301 of the base housing member 101. For example, the interior surface facets 1110 may rest on or against the edge or lip 1301 of the base housing member 101 and adjacent to a periphery of the PCB 1120 after the housing member 1104 is positioned over the PCB 1120 and secured to the base housing member 101.

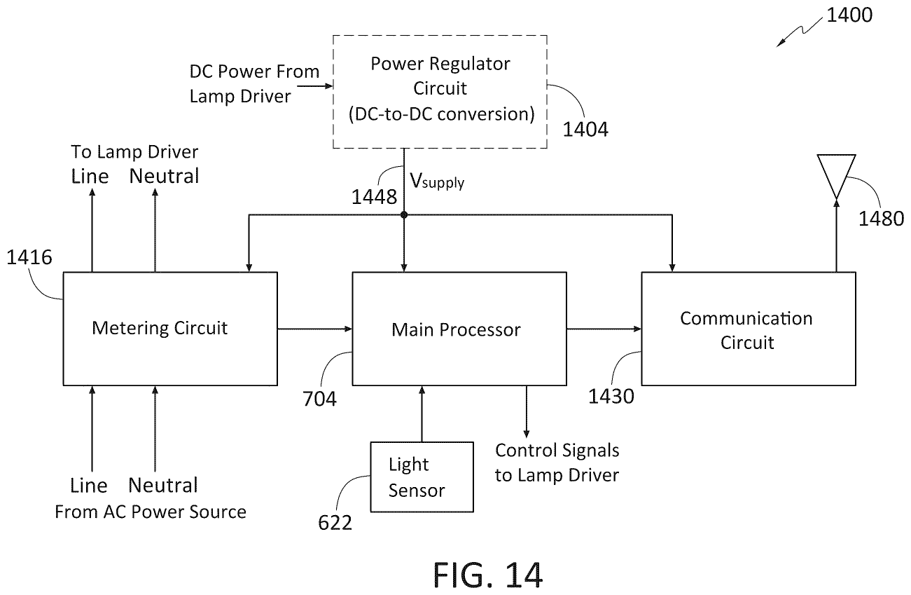

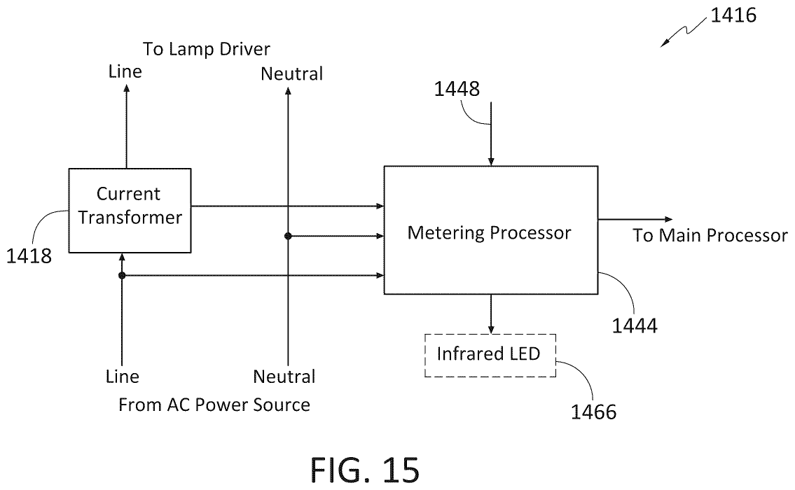

FIG. 14 is an electrical block diagram for an exemplary lighting control device 1400, such as a networked lighting controller, with line current metering capability, in accordance with some embodiments of the present disclosure. The lighting control device 1400 includes a metering circuit 1416, a main processor (e.g., main processor 704), a communication circuit 1430 with associated antenna 1480, and a light sensor 622 (e.g., a photosensor). The lighting control device 1400 may optionally include a power regulator circuit 1404 that includes DC-to-DC voltage conversion when the DC power used to create the supply voltage 1448 for the metering circuit 1416, the main processor 704, the communication circuit 1430, and any other circuity that relies upon such voltage 1448 is unregulated or at too high of a voltage. The components of the lighting controller 1400 may include some or all the electrical components and circuits disposed on or secured to the PCB 102 of the electronic device 100 described above with respect to FIGS. 1-10 or disposed on or secured to the PCB 1120 of the electronic device 1100 described above with respect to FIGS. 11-13. The metering circuit 1416 is described in more detail below with respect to FIG. 15.

In some exemplary embodiments as illustrated in FIGS. 14 and 15, a lighting control apparatus, such as or which may include lighting control device 1400, is connectable to at least a line conductor of an alternating current (AC) power source (e.g., utility power supplied to a utility or streetlight pole) and at least a line conductor of a lamp driver, such as an LED driver of a streetlight luminaire. According to some embodiments, the lighting control apparatus 1400 includes a power metering circuit 1416, a processor 704, and a communication circuit 1430. In other embodiments, the lighting control apparatus 1400 includes a light sensor 622 and associated circuitry to form an ambient light sensor (ALS.) The metering circuit 1416 is configured for coupling to at least the line conductor of the AC power source and at least the line conductor of the lamp driver. According to some embodiments such as the embodiment illustrated in FIG. 14, the metering circuit 1416 is further configured for coupling to the neutral conductor of the AC power source and the neutral conductor of the lamp driver to pass AC power from the AC power source to the lamp driver. In some embodiments, the metering circuit 1416 is configured to meter AC power with a root mean square (rms) voltage in a range of approximately 120 VAC to approximately 480 VAC. Such range of AC power is generally used in connection with typical lower power use cases, such as in streetlights, at residential service points, and at light commercial service points.

The main processor 704 is a processor or controller with moderate processing power sufficient to acquire a sensing signal from the metering circuit 1416, process the sensing signal into a format for communication by the communication circuit 1430, and generate and provide lighting control signals to the lamp driver to which the main processor 704 is electrically connected based on, for example, an output of the light sensor 622 or a light sensing system 1102 that includes the light sensor 622. In some embodiments, the communication circuit 1430 includes a cellular modem 702 (e.g., an LTE modem or a 5G modem) to provide wireless communication over a cellular network. Alternatively or additionally, the communication circuit 1430 may include other communication modems or transceivers to facilitate communication over wired or other wireless networks. The main processor 704 supplies the appropriately formatted sensing signal acquired from the metering circuit 1416 to the communication circuit 1430 to communicate the formatted sensing signal and its embedded metering data to a remote computing system, such as a monitoring and management software platform executing on a cloud server. The main processor 704 may also communicate other data and information via the communication circuit 1430, including operating data and lamp status data, as well as receive through the communication circuit 1430 lighting control signals, firmware updates, and other instructions from the remote computing system.

According to some exemplary embodiments as illustrated in FIG. 15, the power metering circuit 1416 includes a current transformer 1418 and a metering processor 1444. The power metering circuit is arranged to detect AC current passing through the line conductor of the lamp driver and output a sensing signal corresponding to the AC current detected by the current transformer 1418. The metering processor 1444 processes and stores the output voltage of the current transformer 1418, which is directly proportional to the AC current passing through the conductor around which the current transformer 1418 is positioned. Use of a current transformer 1418 instead of a shunt resistor to detect AC current eliminates the need for a digital sampling circuit to be connected to the AC line, thereby also eliminating the need for additional circuitry and cost to isolate the AC signal from the digital sampling circuit to ensure accurate current readings. Use of the current transformer 1418 enables the power metering circuit 1416 to have a metering accuracy of about +/−0.5%.

According to some further exemplary embodiments, the lighting control apparatus 1400 further includes a power regulator circuit 1404, such as where the metering circuit 1416, the main processor 704, the communication circuit 1430, and other components of the lighting control apparatus 1400 requiring a direct current (DC) supply voltage 1448 rely on an unregulated DC power source or a DC power source providing a voltage greater than necessary to supply the DC supply voltage 1448. In such embodiments, the power regulator circuit 1404 may provide a DC-to-DC voltage conversion, such as a down conversion from the DC source voltage to the DC supply voltage 1448 used by the main processor 704, the metering circuit 1416, and the communication circuit 1430, as well as perform voltage regulation. In one embodiment, the power regulator circuit 1404 receives DC power from a lamp driver (e.g., LED driver) of a streetlight. Where the lamp driver operates in accordance with one or more Digital Addressable Lighting Interface (DALI) standards, such as the DALI D4i standard, and supplies an auxiliary output voltage, the voltage supplied by the lamp driver to the power regulator circuit 1404 may be about 24V DC. The supply voltage 1448 output by the power regulator 1404 may be about 3V DC or such other voltage as required by the metering circuit 1416, the main processor 704, the communication circuit 1430, and other electrical components of the lighting control apparatus 1400.

According to some exemplary embodiments, the metering circuit 1416, the main processor 704, the communication circuit 1430, and the light sensor 622 form part of a lighting control device 1400 in a multi-component lighting control apparatus. According to one exemplary embodiment, the components of the lighting control device 1400 are attached to one or both sides of a printed circuit board, such as the PCB 102 or the PCB 1120. For example, as illustrated in FIGS. 6 and 7, some components of the lighting control device (e.g., the main processor 704, the communication circuit 1430 (e.g., cellular modem 704), the light sensor 622, and the metering processor 1444) may be attached to one side of the PCB 102, 1120 and the current transformer 1418 and other components may be attached to the other side of the PCB 102, 1120. Alternatively, the components of the lighting control device 1400 may be attached to multiple PCBs or on just one side of the PCB 102, 1120.

In embodiments where the current transformer 1418 is attached to the bottom side of the PCB 102, 1120 as illustrated in FIGS. 6 and 12, the current transformer 1418 is preferably positioned on the PCB 102, 1120 such that at least part of the current transformer 1418 resides in the passageway 133 of the conduit 112 of the lighting control device (e.g., electronic device 190). Depending on the configuration of the current transformer 1418 to handle the AC voltage and current ranges expected from the AC power source, the height of the current transformer 1418 may be such that the component cannot fit in the space between the bottom side of the PCB 102, 1120 and a floor on the top side 110 of the base housing member 101. Therefore, positioning the current transformer 1418 on the bottom side of the PCB 102, 1120 such that at least part of the current transformer 1418 extends into the passageway 133 provides sufficient clearance for the current transformer 1418 while allowing the lighting control device to maintain a low profile and the current transformer 1418 to be positioned on the side of the lighting control device at which the line conductor current from the AC power source enters the lighting control device (e.g., through the passageway 133).

In further exemplary embodiments in which the lighting control apparatus or its lighting control device is configured similar to the configuration of the electronic device 190, 1100 illustrated in FIG. 1 or FIG. 11, the line and/or neutral conductors (e.g., insulated or bare wires) connecting the AC power source to the metering circuit 1416 and connecting the metering circuit 1416 to the lamp driver pass through the passageway 133 of the conduit 112. For example, the line and neutral conductors of the AC power source pass through the passageway 133 of the conduit 112 to the power metering circuit 1416 and the line and neutral conductors of the lamp driver pass through the passageway 133 of the conduit 112 from the power metering circuit 1416. In alternative embodiments, lighting control signals from the main processor 704 (e.g., lighting controller) pass through the passageway 133 of the conduit 112 to the lamp driver. Where the lamp driver is compliant with one or more of the DALI protocols (e.g., DALI-2 and/or D4i), the lighting control signals are compliant with the applicable DALI protocol or protocols. Where the lamp driver is not DALI-compliant, the lighting control signals may be other conventional lighting control signals, such as pulse wave modulation signals or analog voltage control signals (e.g., 0-10V dimming).

In some alternative embodiments, the metering processor 1444 may be optionally coupled to an infrared (IR) LED 1466. In such cases, the metering processor 1444 controls the IR LED to report the metering data in real time for on-location detection by an IR sensor (e.g., a handheld sensor used by installation or maintenance personnel).

According to further alternative embodiments, a lighting control apparatus includes the lighting control device 1400 described above with respect to FIGS. 14 and 15, as packaged in the form of the electronic device 190 of FIG. 1 or the electronic device 1100 of FIG. 11. Therefore, according to such embodiments, the lighting control apparatus includes the lighting control device 1400 together with the mounting bracket 104. As so arranged, the lighting control apparatus may be mounted to a structure, such as a streetlight luminaire that includes a lamp driver (e.g., LED driver) and a lamp (e.g., LED module(s)) driven by the lamp driver.

The claims appended hereto are meant to cover all modifications and changes within the scope and spirit of the present disclosure.

What is claimed is:

1. A retaining apparatus for a printed circuit board, the retaining apparatus comprising:
a support member having a first side and a second side;
a plurality of flexible finger members positioned proximate a periphery of the support member, each finger member extending away from the second side of the support member and having a restoring force toward a center of the support member; and
at least one wall member extending away from the second side of the support member, the at least one wall member being sized and shaped to restrict deflection of at least one area of the printed circuit board in an event that the printed circuit board is subjected to an externally applied force printed circuit board.

2. The retaining apparatus of claim 1, wherein the support member includes a substantially flat section and an angled section joined to the substantially flat section, the angled section extending to the periphery of the support member.

3. The retaining apparatus of claim 2, wherein the substantially flat section of the support member has a circular shape.

4. The retaining apparatus of claim 1, wherein the support member, the finger members, and the at least one wall member are formed as a single molded component.

5. The retaining apparatus of claim 1, further comprising:
a light guide positioned between the support member and an expected location of a light sensor secured to the printed circuit board.

6. The retaining apparatus of claim 1, wherein at least some of the finger members include tabs on inward-facing sides thereof, the tabs providing support for the printed circuit board upon positioning of the finger members about the printed circuit board.

7. The retaining apparatus of claim 6, wherein at least three of the finger members include tabs on the inward-facing sides thereof.

8. The retaining apparatus of claim 1, wherein the at least one wall member includes multiple wall members.

9. The retaining apparatus of claim 1, wherein the at least one area of the printed circuit board for which deflection is restricted includes an area of the printed circuit board to which at least one component is attached.

10. A printed circuit board module comprising:
a retaining apparatus including:
a support member having a first side and a second side;
a plurality of flexible finger members positioned proximate a periphery of the support member, each finger member extending away from the second side of the support member and having a restoring force toward a center of the support member; and
at least one wall member extending away from the second side of the support member; and
a printed circuit board having attached thereto at least one component, wherein the printed circuit board is retained by and between the finger members of the retaining apparatus and wherein the at least one wall member of the retaining apparatus is sized and shaped to restrict deflection of at least one area of the printed circuit board in an event that the printed circuit board is subjected to an externally applied force.

11. The printed circuit board module of claim 10, further comprising:
at least one antenna disposed at least partially on the first side of the support member of the retaining apparatus.

12. The printed circuit board module of claim 10, wherein the support member of the retaining apparatus includes a substantially flat section and an angled section joined to the substantially flat section, the angled section extending to the periphery of the support member.

13. The printed circuit board module of claim 10, wherein the at least one component includes a light sensor, the printed circuit board module further comprising:
a light guide positioned to direct incident light toward the light sensor.

14. The printed circuit board module of claim 10, wherein at least some of the finger members of the retaining apparatus include tabs on inward-facing sides thereof and wherein peripheral areas of the printed circuit board rest upon the tabs such that the tabs provide support for the printed circuit board.

15. The printed circuit board module of claim 10, wherein the at least one wall member of the retaining apparatus includes multiple wall members.

16. The printed circuit board module of claim 10, wherein the at least one area of the printed circuit board for which deflection is restricted includes an area of the printed circuit board to which the at least one component is attached.

17. The printed circuit board module of claim 10, wherein the retaining apparatus is formed as a single molded component.

18. A printed circuit board module comprising:
a retaining apparatus including:
a support member having a first side and a second side;
a plurality of flexible finger members positioned proximate a periphery of the support member, each finger member extending away from the second side of the support member and having a restoring force toward a center of the support member; and
a plurality of wall members extending away from the second side of the support member; and
a printed circuit board having attached thereto a plurality of components, wherein the printed circuit board is retained between the finger members of the retaining apparatus and wherein the wall members of the retaining apparatus are sized and shaped to restrict deflections of multiple areas of the printed circuit board in an event that the printed circuit board is subjected to at least one externally applied force.

19. The printed circuit board module of claim 18, wherein the plurality of components includes a light sensor, the printed circuit board module further comprising:
a light guide extending from the second side of the support member toward the printed circuit board so as to direct light incident upon an input to the light guide toward the light sensor.

20. An electronic device comprising:
a printed circuit board module including:
a retaining apparatus including:
a support member having a first side and a second side;
a plurality of flexible finger members positioned proximate a periphery of the support member, each finger member extending away from the second side of the support member and having a restoring force toward a center of the support member; and
at least one wall member extending away from the second side of the support member; and
a printed circuit board having one or more components attached thereto, wherein the printed circuit board is retained between the finger members of the retaining apparatus and wherein the one or more wall members of the retaining apparatus are sized and shaped to restrict deflections of at least one area of the printed circuit board in an event that the printed circuit board is subjected to at least one externally applied force; and
a base member, wherein the printed circuit board is positioned upon at least a portion of a first side of the base member.
